(19) United States
(12) Patent Application Publication
(10) Pub. No.: US 2009/0153367 A1
(43) Pub. Date: Jun. 18, 2009

(54) PEN-TYPE PORTABLE WIRELESS TERMINAL

(75) Inventor: Yong Whi Lee, Seoul (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/330,210

(22) Filed: Dec. 8, 2008

(30) Foreign Application Priority Data
Dec. 14, 2007 (KR) 10-2007-0130593

(51) Int. Cl. H03K 17/94; H04M 3/42

(52) U.S. Cl. 341/20; 455/415

(57) ABSTRACT

A pen-type portable wireless terminal is provided. The pen-type portable wireless terminal includes a sensor unit located in an end part of a pen-type housing, the sensor unit to sense movement of the end part; an identification unit to identify at least one of a character and a numeral from the movement sensed by the sensor unit; a display unit to display the identified character or numeral; a wireless transmitting/receiving unit to communicate wirelessly with the outside; and a controller to transmit information corresponding to the identified character or numeral through the wireless transmitting/receiving unit.

### CROSS REFERENCE TO RELATED APPLICATION

This application claims priority from and the benefit of Korean Patent Application No. 2007-0130593, filed on Dec. 14, 2007, which is hereby incorporated by reference for all purposes as if fully set forth herein.

### BACKGROUND OF THE INVENTION

1. Field of the Invention

The present invention relates to a pen-type portable wireless terminal, and more particularly, to a pen-type portable wireless terminal that includes a sensor for sensing movement of an end part of the pen-type portable wireless terminal, to input a character or numeral.

2. Discussion of the Invention

Portable wireless terminals are widely used for enabling convenient wireless communication at any location. Current portable wireless terminals provide a variety of functions in addition to a conventional portable communication service as processor performance improves and memory resources increase.

In a conventional portable wireless terminal, a keypad and a touch screen may be used as a character and numeral input means. When using the keypad, the number of characters available for input is determined according to the number of keys, and more complex steps are needed to increase the number of the available characters. When using the touch screen, input is more convenient than with the keypad, but the size of the touch screen should be relatively large. Such requirement of a large touch screen puts a design limitation on how small the portable wireless terminal may be.

The conventional keypad or touch screen therefore may have a limited ability to meet the trend of miniaturization of modern portable wireless terminals.

### SUMMARY OF THE INVENTION

The present invention provides a portable wireless terminal having a pen-type shape to provide enhanced portability, and to input a character and numeral by using movement of a pen-type portable wireless terminal.

Additional features of the invention will be set forth in the description which follows, and in part will be apparent from the description, or may be learned by practice of the invention.

The present invention discloses a portable wireless terminal that includes: a sensor unit located in an end part of a pen-type housing, the sensor unit to sense movement of the end part; an identification unit to identify at least one of a character and a numeral from the movement sensed by the sensor unit; a display unit to display the identified character or numeral; a wireless transmitting/receiving unit for wireless communication with the outside; and a controller to transmit information that corresponds to the identified character or numeral through the wireless transmitting/receiving unit.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a side and end view of a pen-type portable wireless terminal according to an exemplary embodiment of the present invention.

FIG. 1B is a view showing a voice communication mode in the pen-type portable wireless terminal of FIG. 1A.

FIG. 1C is a view showing a message transmitting or receiving mode in the pen-type portable wireless terminal of FIG. 1A.

FIG. 1D is a view showing a state for charging the pen-type portable wireless terminal of FIG. 1A.

FIG. 2 is a block diagram showing a configuration of an internal part of the pen-type portable wireless terminal of FIG. 1A.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

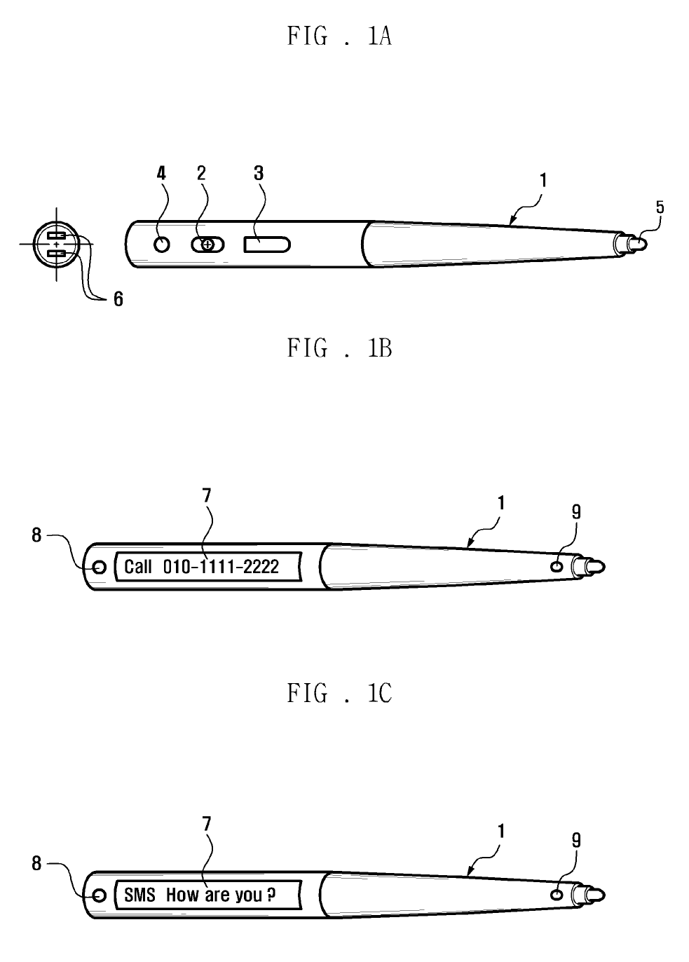

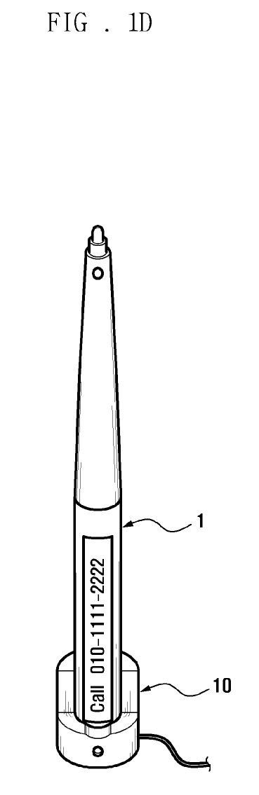

FIG. 1A, FIG. 1B, FIG. 1C, and FIG. 1D are external views of a pen-type portable wireless terminal according to an exemplary embodiment of the present invention. Referring to FIG. 1A, FIG. 1B, FIG. 1C, and FIG. 1D, a pen-type portable wireless terminal 1 according to an exemplary embodiment of the present invention includes a sensor unit 5, a display unit 7, a microphone 9, a speaker 8, an LED (Light Emitting Diode) 4, a power button 2, a mode conversion button 3, and a charging terminal 6.

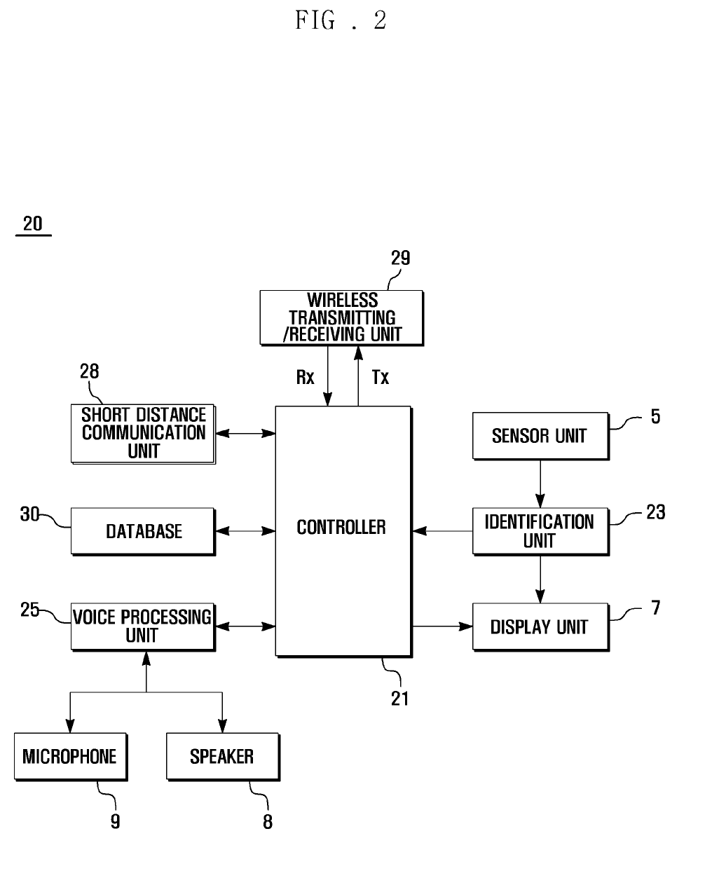

FIG. 2 is a block diagram showing a configuration of an internal part of the pen-type portable wireless terminal. Referring to FIG. 2, the internal part 20 of the pen-type portable wireless terminal 1 includes a controller 21, a voice processing unit 25, a wireless transmitting/receiving unit 29, a database 30, a short distance communication unit 28, and an identification unit 23.

The portable wireless terminal 1 has a pen-type housing, and the sensor unit 5 is installed in an end part of the housing. The sensor unit 5 may be an optical sensor for emitting light and sensing the reflected light. Further, the sensor unit 5 may be a ball sensor for sensing movement of the portable wireless terminal 1 by rotation of a ball member.

The identification unit 23 of the portable wireless terminal 1 receives movement signals from the sensor unit 5 and extracts a movement path therefrom, and identifies a character or numeral corresponding to the extracted movement path. Identification of characters or numerals through movement signals received from a sensor unit is well known in the art.

The display unit 7 is installed on an outside part of the pen-type housing and displays the identified character or numeral.

When input from the sensor unit 5 is completed, the controller 21 retrieves a name or phone number of a call party from the database 30, including phone number and name information, using the identified character or numeral.

The wireless transmitting/receiving unit 29 includes an RF (radio frequency) circuit for wireless communication with the outside, and communicates with a base station under the control of the controller 21. The portable wireless terminal 1 may further include the short distance wireless communication unit 28, such as a Bluetooth and NFC (near field communication) unit, in addition to the wireless transmitting/receiving unit 29. The portable wireless terminal 1 may transmit and receive information to and from another portable wireless terminal at a short distance using the short distance wireless communication unit 28.

The mode conversion button 3 initiates and releases a phone call, converts into a transmitting or receiving mode, and selects other menus according to user input.

The speaker 8 is installed in an upper part of the pen-type housing, and the microphone 9 is installed in a lower part of the pen-type housing, thereby enabling voice communication without a separate earphone.

The LED 4 lights up when operating the sensor unit 5, to display an operation state. The charging terminal 6 is installed in an upper end part of the pen-type housing to be connected with a charger 10, as shown in FIG. 1D, thereby enabling the portable wireless terminal to be charged. The power button 2 is installed between the LED 4 and the mode conversion button 3 for turning power on and off.

An operation of the pen-type portable wireless terminal 1 having the above-described configuration is described with reference to FIG. 1B and FIG. 1C.

For voice communication, a user presses the power button 2 to turn on power and then presses the mode conversion button 3 to enter a dialing mode (Call). Here, the user confirms whether the mode conversion is performed through the light of the LED 4.

In the dialing mode, the user writes a phone number by contacting the sensor unit 5 of the pen-type portable wireless terminal 1 on a surface with a writing motion, which may be a non-reflective surface. If the identification unit 23 identifies the phone number or character through movement of the sensor unit 5, the identified phone number or character is displayed on the display unit 7. When numeral or character input is complete, the controller 21 retrieves a phone number of a call party corresponding to the input characters from the database 30. The user may then click the mode conversion button 3 to enter a phone call mode. Alternatively, the user may initiate a phone call using a predetermined symbol character such as ⊚, instead of clicking the mode conversion button 3.

The user may perform voice communication using the speaker 8 and the microphone 9 of the pen-type portable wireless terminal 1.

For message transmission, the user manipulates the mode conversion button 3 so that the portable wireless terminal 1 enters into a message transmitting mode (SMS). If the user writes a message by contacting the sensor unit 5 on a surface with a writing motion, the message is identified in the identification unit 23 through movement of the sensor unit 5 and is displayed on the display unit 7. When the message input is complete, the user manipulates the mode conversion button 3 to enter the dialing mode (Call) and inputs a phone number or name of a call party to send the message.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A portable wireless terminal, comprising:
a sensor unit located in an end part of a pen-type housing, the sensor unit to sense movement of the end part;
an identification unit to identify at least one of a character and a numeral from the movement sensed by the sensor unit;
a display unit to display the identified character or numeral;
a wireless transmitting/receiving unit to communicate wirelessly with the outside; and
a controller to transmit information that corresponds to the identified character or numeral through the wireless transmitting/receiving unit.

2. The portable wireless terminal according to claim 1, wherein the sensor unit comprises an optical sensor to emit light and sense the reflected light.

3. The portable wireless terminal according to claim 1, wherein the sensor unit comprises a ball sensor to sense rotation of a ball member.

4. The portable wireless terminal according to claim 1, further comprising a storage unit to store a database that has information on at least one of a phone number and a name.

5. The portable wireless terminal according to claim 4, wherein the controller retrieves a call party that corresponds to the character or numeral identified by the identification unit from the database, and displays the call party on the display unit.

6. The portable wireless terminal according to claim 5, further comprising a call button to input a phone call command by a user, when the call party is displayed on the display unit.

7. The portable wireless terminal according to claim 5, wherein a phone call command is input by a user by inputting a predetermined symbol using the sensor unit, after the call party is displayed on the display unit.

8. The portable wireless terminal according to claim 1, wherein a speaker is installed in an end part of the pen-type housing, and a microphone is installed in the other end part of the pen-type housing.

9. The portable wireless terminal according to claim 1, wherein the wireless transmitting/receiving unit comprises a short distance wireless communication unit.

10. The portable wireless terminal according to claim 1, further comprising a mode conversion button to convert into at least one of a voice communication mode and a message transmission mode.
